(19) United States
(12) Patent Application Publication
(10) Pub. No.: US 2026/0190285 A1
(43) Pub. Date: Jul. 2, 2026

(54) COOLER THROUGH WHICH FLUID CAN FLOW FOR COOLING POWER ELECTRONICS

(71) Applicant: Robert Bosch GmbH, Stuttgart (DE)

(72) Inventors: Max Florian Beck, Vaihingen An Der Enz (DE); Valentin Ruedenauer, Reutlingen (DE)

(21) Appl. No.: 19/103,918

(22) PCT Filed: Jul. 7, 2023
(86) PCT No.: PCT/EP2023/068874

§ 371 Date: Feb. 14, 2025

(30) Foreign Application Priority Data
Aug. 31, 2022 (DE) 10 2022 209 015.2

(51) Int. Cl. H05K 7/20

(52) U.S. Cl. CPC H05K 7/20263; H05K 7/20927

(57) ABSTRACT

The present invention relates to a cooler (1) through which fluid can flow for cooling power electronics (200) comprising a first metal part (11), a second metal part (12), a cooling structure (14) and a reinforcing part (13). The first metal part (11) and the second metal part (12) are connected to each other and define a cooling channel (10) between them through which a fluid can flow. The first metal part (11) comprises a receiving area (110) for receiving the power electronics (200) to be cooled. The cooling structure (14) is located in the cooling channel (10) and connected to the first metal part (11) and the second metal part (12). The reinforcing part (13) is secured to the first metal part (11). Furthermore, the invention relates to a power electronics arrangement (1000) having a cooler (1) of this type and power electronics (200).

### BACKGROUND

The present invention relates to a cooler through which fluid can flow for cooling power electronics. The invention also relates to a power electronics arrangement having a cooler through which fluid can flow and power electronics. The power electronics can in particular comprise at least one power semiconductor.

Power semiconductors carry high electrical currents. Together with switching losses, the resulting conduction losses are the cause of high heat dissipation, which must be dissipated over a very small area. The maximum permissible semiconductor temperature is critical to failure, which is why minimizing the thermal resistance between the semiconductor and the coolant is of central importance. For efficient cooling, the power substrates are applied to coolers through which fluid can flow. These coolers are made of aluminum, AlSiC, or copper alloys. Pins or fins are located inside the cooler to increase the heat transfer surface and intensify the heat transfer. In order to achieve a low thermal resistance between a power substrate, in particular an AMB/DBC power substrate (AMB: active metal braze; DBC: direct copper bonding), and the cooler, the power substrate is joined to the cooler by means of a soft soldering process or, optionally, a sintering process. For this purpose, these coolers can be surface-coated with materials suitable for a soft soldering process or a sintering process. In automotive engineering, aluminum coolers, also AlSiC or copper coolers, which consist of a plurality of components that are joined in particular by a brazing process, are frequently known.

### SUMMARY

The cooler through which fluid can flow according to the invention for cooling power electronics has the advantage that the requirements for a pressure drop in a cooling channel of the cooler, for resistance of the cooler to internal pressure in the cooling channel that is built up by a fluid flowing through the cooling channel, and for cooling capacity of the cooler can be met. This is achieved by a cooler through which fluid can flow for cooling power electronics comprising a first metal part, a second metal part, a cooling structure and a reinforcing part. The first metal part and the second metal part are connected to each other and define a cooling channel between them through which a fluid can flow. The first metal part comprises a receiving area for receiving the power electronics to be cooled. The cooling structure is located in the cooling channel and connected to the first metal part and the second metal part. The reinforcing part is secured to the first metal part. The reinforcing part advantageously serves to strengthen the arrangement of the first metal part and the second metal part against the internal pressure prevailing during operation of the cooler. Due to the reinforcing part being an external part, expensive insert parts or intermediate parts are omitted that would be connected to the first metal part and the second metal part, in order for the first metal part and the second metal part to be held together when pressurized, e.g. via tension rods. An external part is particularly understood to be a part that is located in the cooling channel. Thus, a higher pressure drop in the cooling channel can be prevented, which would otherwise be caused by the aforementioned additional support geometry in the cooling channel. In this respect, it is noted that the cooling structure serves/acts as a support structure element, in particular as an inner support structure element, due to its connection to the first metal part and the second metal part. Furthermore, the present invention can ensure or increase the cooler's resistance to internal pressure in the cooling channel without having to select a sufficiently high thickness (material thickness) of the individual metal parts. Since a thermal resistance of the first metal part and/or the second metal part depends directly on a corresponding thickness of the first metal part and/or the second metal part, the provision of the reinforcing part may result in the first metal part and/or the second metal part having the lowest possible thickness. Thus, a high cooling capacity of the cooler may be maintained. In addition, a higher degree of flexibility in the choice of a suitable material for the first metal part and/or the second metal part is ensured with respect to strength. In particular, for the first metal part and/or the second metal part, materials may be selected that have sufficient strength and are simultaneously suitable for a hard soldering process when the cooler is to be manufactured by a hard soldering process. The reinforcing part (reinforcing element) may also be referred to in the context of the present invention as an external support structure element for internal pressure support of the cooler. The reinforcing part may preferably be made of metal. In the context of the present invention, a metal part is to be advantageously understood as a part formed from at least one metal or metal alloy. It should further be noted that the reinforcing part is not used to define the cooling channel due to its location on the first metal part. It is possible for the cooler to comprise a plurality of reinforcing parts.

Advantageously, the cooling channel is circumferentially enclosed exclusively by the first metal part and the second metal part. The cooling channel is formed by the first metal part and the second metal part in an advantageous manner as a cooling channel closed circumferentially. The first metal part and the second metal part are advantageously directly connected to one another. In particular, a direct connection means that between the first metal part and the second metal part there is only one connecting material by means of which the two metal parts are connected together. The connecting material is preferably a hard soldering layer.

The first metal part, the second metal part and the reinforcing part advantageously form a housing. In particular, the cooling channel corresponds to an internal space of the housing defined by the first metal part and the second metal part. Preferably, an inlet and an outlet for a fluid used as a coolant are located directly on the housing.

Advantageously, the first metal part is located between the reinforcing part and the second metal part. Therefore, in the context of the present invention, the first metal part may particularly also be referred to as a metallic intermediate part. Advantageously, the first metal part and the second metal part are located on one another. The reinforcing part is advantageously secured to an outer surface of the first metal part.

The cooler preferably comprises a longitudinal direction, a width direction (transverse axis), and a thickness direction (height axis). The longitudinal direction preferably corresponds to a longitudinal direction of the reinforcing part. The width direction preferably corresponds to a width direction of the reinforcing part. The thickness direction preferably corresponds to a thickness direction of the reinforcing part. The cooler further preferably comprises a first end and a second end in the longitudinal direction, as well as a first edge and a second edge in the width direction.

Preferably, the reinforcing part is located on the first metal part at least partially outside an overlap area between the first metal part and the cooling structure and/or between the second metal part and the cooling structure. That is, in particular, at least one area of the reinforcing part is located outside the overlap area. The overlap area between the first metal part and the cooling structure and/or between the second metal part and the cooling structure is an area where the first metal part and the cooling structure and/or the second metal part and the cooling structure overlap. In other words, the reinforcing part is preferably applied at least in part to an area of the first metal part in which the cooler is not supported by the cooling structure. The reinforcing part thus increases the resistance to the prevailing internal pressure in the weaker regions of the cooler, and the flow inside the cooling channel is not influenced by the reinforcing part. Particularly in the area of the applied power electronics, that is, in the receiving area, relatively thin material thicknesses can be employed for the first metal part, since the cooling channel in this area is supported upwards and downwards by the inserted cooling structure. This allows minimum heat transfer resistance between the power electronics and the fluid used as the coolant.

According to an advantageous embodiment of the invention, the reinforcing part may be located on the first metal part exclusively outside the overlap area. This means in particular that the reinforcing part does not overlap with or cover the cooling structure. In other words, the reinforcing part does not overlap with the overlap area. In particular, the reinforcing part can be located at a distance from the overlap area or the cooling structure.

According to an alternative advantageous embodiment of the invention, the reinforcing part may be located partially outside the overlap area. The reinforcing part overlaps with the cooling structure or the overlap area. It is to be understood that the overlap of the reinforcing part with the cooling structure or the overlap area is advantageously a partial overlap. That is in particular to say that at least one area of the reinforcing part is located outside the overlap area and at least one area of the reinforcing part overlaps with the cooling structure or the overlap area, respectively. The reinforcing part can be located substantially outside the overlap area.

Preferably, at least one area of the reinforcing part may be located on the first metal part exclusively outside the overlap area and/or at least one area of the reinforcing part may overlap with the cooling structure. Thus, for example, an area of the reinforcing part that extends longitudinally from one end of the cooler to the receiving area can overlap with the cooling structure or cover the cooling structure, whereby an area of the reinforcing part that extends in the width direction from an edge of the cooler to the receiving area is located exclusively outside the overlap area, or vice versa. It is also conceivable that both the area of the reinforcing part extending in the longitudinal direction from one end of the cooler to the receiving area and the area of the reinforcing part extending in the width direction from one edge of the cooler to the receiving area overlap with the cooling structure or cover the cooling structure.

In an overlapping arrangement of the reinforcing part with the cooling structure, preferably a measure of the overlap between an area of the reinforcing part and the cooling structure in the extension direction of the area is a maximum of ten times, more preferably a maximum of five times, the thickness of the first metal part.

Preferably, the cooler, in particular the housing of the cooler, comprises a recess. Preferably, the receiving area of the first metal part is located at the location of the recess. Preferably, the recess defines the receiving area.

The recess may preferably be made of metal. In other words, preferably the reinforcing part may comprise the recess. The recess may preferably be defined by an inner wall of the reinforcing part. The recess preferably at least partially surrounds the receiving area circumferentially, and in particular, completely. According to a particularly advantageous embodiment of the invention, the recess is closed circumferentially/in the circumferential direction.

Alternatively, the recess may preferably be formed between two reinforcing parts.

Preferably, the thickness of the reinforcing part is greater than or equal to the thickness of the first metal part, in particular the receiving area of the first metal part.

Furthermore, preferably the sum of the thickness of the reinforcing part and the thickness of the first metal part, in particular the receiving area of the first metal part, is greater than or equal to the thickness of the second metal part.

According to an advantageous embodiment of the invention, the reinforcing part extends in the longitudinal direction from one end of the cooler (only) to the receiving area. Preferably, the cooler may comprise two reinforcing parts, wherein the one reinforcing part extends longitudinally from a first end of the cooler (only) to the receiving area and the other reinforcing part extends longitudinally from a second end of the cooler (only) to the receiving area.

According to an alternative embodiment of the invention, the reinforcing part is formed continuously in the longitudinal direction. In the context of the invention, a continuous reinforcing part means in particular that the reinforcing part is at least partially continuously formed. In other words, at least one area of the reinforcing part is continuously formed. That is, in particular, the at least one area of the reinforcing part extends longitudinally from a first end of the cooler to a second end of the cooler. In this configuration of the cooler, the reinforcing part may preferably comprise a first end area, at least one edge area, and a second end area. Preferably, the first end area may extend in the longitudinal direction from a first end of the cooler (only) to the receiving area and the second end area may extend in the longitudinal direction from a second end of the cooler (only) to the receiving area, wherein the at least one edge area extends in the width direction from an edge of the cooler (only) to the receiving area. The at least one edge area is preferably located between the first end area and the second end area. Preferably, the at least one edge area interconnects the first end area and the second end area. A part of the first end area, at least one edge area and a part of the second end area, may correspond to the aforementioned area of the reinforcing part extending longitudinally from the first end of the cooler to the second end of the cooler, which is thus continuously formed. Particularly preferably, the reinforcing part comprises two edge regions.

Preferably, the reinforcing part may be provided at the inlet and/or outlet of the cooler.

Preferably, the reinforcing part is located on the first metal part between the first metal part and the second metal part at at least one connection point, in particular at a plurality of connection points, particularly preferably at each connection point. Thus, the cooler is reinforced at the at least one connection point between the first metal part and the second metal part by means of the reinforcing part.

Preferably, the cooler is configured such that the cooler has a resistance to a relative internal pressure of greater than 2 bar in the cooling channel. Furthermore, preferably, the cooler may be configured to withstand a maximum internal relative pressure of 2.5. That is in particular to say that the cooler is constructed to withstand the internal pressure over its lifetime without, or at least without significant, deformation. The relative internal pressure means a pressure relative to the ambient pressure or atmospheric pressure.

The reinforcing part is preferably plate-shaped/formed as a plate, in particular an oval-shaped plate.

Preferably, the first metal part is plate-shaped, wherein the second metal part comprises a plate-shaped area and a trapezoidal area in cross-section. The second metal part can in particular be configured as a deep-drawing part. However, it is also possible for the first metal part to comprise a plate-shaped area and a trapezoidal area in cross-section and the second metal part to be plate-shaped.

The first metal part and/or the second metal part is/are preferably configured as sheet metal(s).

The cooling structure may preferably comprise a cooling fin structure and/or a pin structure (cooling pin structure). It is also conceivable that the cooling structure alternatively or additionally also comprises a cooling structure element or a plurality of cooling structure elements that have a different shape than a cooling fin or pin. It is in particular possible for the cooling structure to have a plurality of cooling structure elements of different shapes. For example, the cooling structure may comprise a cooling fin and a pin, or a plurality of cooling fins, and a plurality of pins. In the context of the present invention, a cooling fin and a pin may each be referred to as a cooling structure element.

The cooling structure in the context of the present invention is preferably understood as a surface-enhancing, flow-conducting and heat-transfer-increasing structure.

The cooling fin structure may preferably comprise (only) a cooling fin or a plurality of cooling fins, which are preferably located one behind the other in a flow direction. The flow direction corresponds in particular to a main flow direction of a fluid used as a coolant, which flows through openings formed by the cooling fin(s). In particular, the main flow direction is in this case the direction in which the fluid mainly flows, i.e., the direction in which a velocity component of the fluid is greater than a velocity component of the fluid in a direction perpendicular to the main flow direction. The main flow direction may preferably correspond to a direction in which the fluid enters the cooler, through which fluid can flow. The main flow direction is preferably parallel to the longitudinal direction of the cooler.

The cooling fin structure may in particular also be referred to as a turbulator. The cooling fin is formed by a wave profile periodically repeating in a repeating direction. The pin structure may preferably comprise (only) one or a plurality of pins, which are preferably located in the flow direction and/or in a direction perpendicular to the flow direction.

The cooling structure may preferably be made, at least partially, particularly completely, of a material and/or coated with a material that features a coefficient of thermal conductivity greater than 200 W/(m-K). Advantageously, the at least cooling structure may be made of aluminum or coated with aluminum. In particular, these configurations relate to the cooling structure elements of the cooling structure.

The entire cooler, that is, the first metal part, the second metal part, the reinforcing part and the cooling structure, may preferably be made and/or coated from the same material, preferably aluminum or e.g. copper or stainless steel.

In the context of the present invention, the fluid flowing through the cooler may in particular also be referred to as cooling fluid.

The present invention further relates to a power electronics arrangement comprising a cooler, through which fluid can flow, as described above, and power electronics. The power electronics are located on the receiving area of the first metal part, in particular in a fixed manner.

Preferably, the power electronics can comprise one power electronics unit or several power electronics units.

In the context of the invention, a power electronics unit can in particular also be referred to as a power module. The power electronics unit preferably comprises a carrier plate and/or conductor paths and/or one or a plurality of power semiconductors.

The power electronics component(s) are preferably joined to the cooler through which fluid can flow or the receiving area of the first metal part by means of a layer generated by a soft soldering process or a sintering process, which can thus be referred to as a soft soldering layer or a sintering layer, respectively.

Advantageously, the power electronics are only located on the receiving area of the first metal part. That is in particular to say that the power electronics are not located on the reinforcing part.

The power electronics are preferably located in an advantageous manner in the recess of the housing described above.

As already described above, the recess can be configured according to an advantageous embodiment of the invention in the reinforcing part. That is, the recess is formed in the reinforcing part. Preferably, the power electronics protrude in the thickness direction over an outer surface of the reinforcing part. The power electronics can preferably be located at a distance from the inner wall of the reinforcing part. Alternatively, preferably, the power electronics may be in contact with the interior wall of the reinforcing part. Thus, the power electronics may be pre-centered to connect with the first metal part. In addition, a part of the heat generated by the power electronics can be dissipated via the contact of the power electronics with the inner wall of the reinforcing part.

### BRIEF DESCRIPTION OF THE DRAWINGS

In the following sections, exemplary embodiments of the invention are described in detail with reference to the accompanying drawing, wherein identical or functionally identical components are each designated by the same reference number. The drawings show:

FIG. 1 is a schematic simplified perspective sectional view of a power electronics arrangement according to the invention comprising power electronics and a cooler, through which fluid can flow, according to a first exemplary embodiment of the invention,

FIG. 2 is a schematic simplified perspective sectional view of the power electronics arrangement according to the invention shown in FIG. 1,

FIG. 3 is a schematic simplified sectional view of the power electronics arrangement according to the invention shown in FIG. 1, and

FIG. 4 is a schematic simplified perspective view of a power electronics arrangement according to the invention comprising power electronics and a cooler, through which fluid can flow, according to a second exemplary embodiment of the invention.

### DETAILED DESCRIPTION

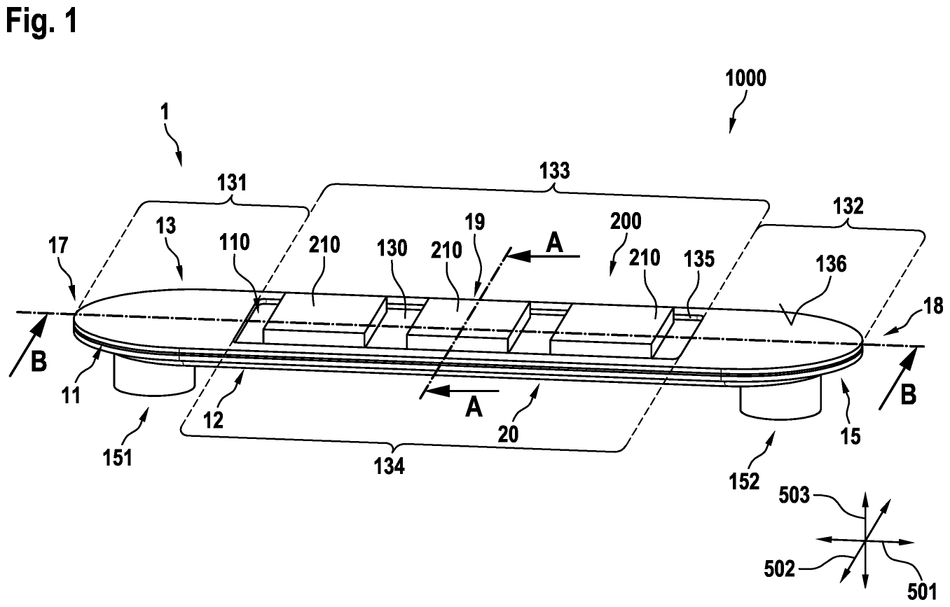

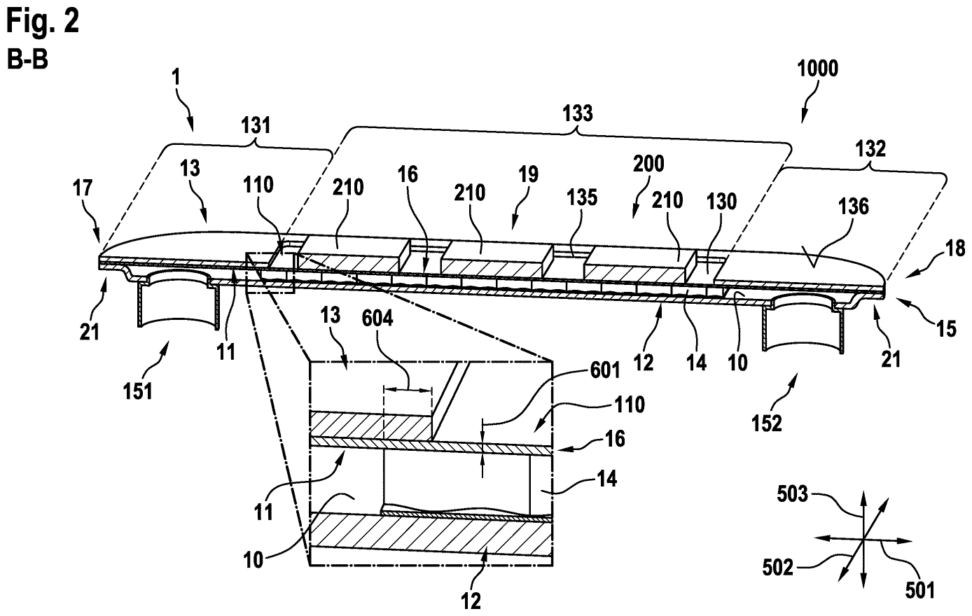

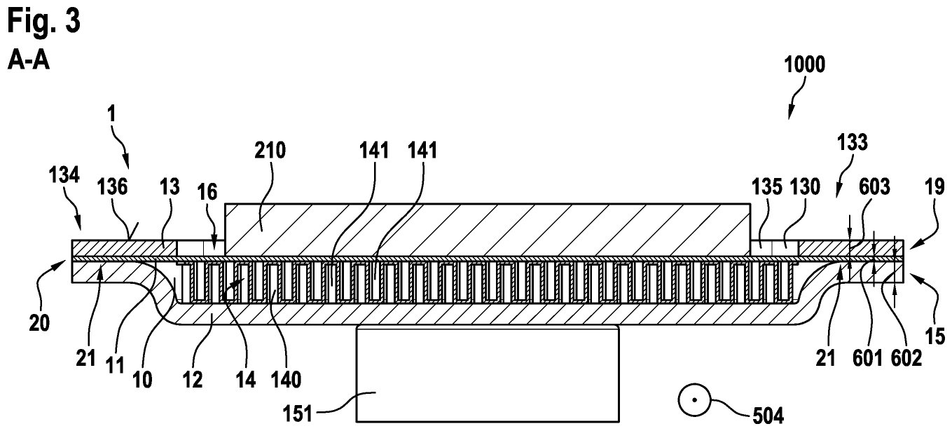

Referring to FIGS. 1 through 3, a power electronics arrangement 1000 according to the invention comprising power electronics 200 and a cooler 1 through which fluid can flow for cooling the power electronics 200 according to a first exemplary embodiment of the invention is described below. FIG. 1 shows a perspective view of the power electronics arrangement 1000. FIG. 2 shows a perspective view of the power electronics arrangement 1000 along line B-B (in the width direction 502) in FIG. 1, wherein in FIG. 2 additionally a part of the cooler 1 is shown at an enlarged scale. FIG. 3 shows a section of the power electronics arrangement 1000 along line A-A (in the longitudinal direction 501) in FIG. 1.

As can be seen from FIGS. 1 to 3, the cooler 1 through which fluid can flow comprises a first metal part 11, a second metal part 12, a cooling structure 14 and a reinforcing part 13.

The first metal part 11 and the second metal part 12 are directly connected to each other and define a cooling channel 10 between them, through which a fluid can flow that is used as a coolant and in which the cooling structure 14 is located. As can in particular be seen in FIG. 3, the cooling channel 10 is circumferentially enclosed exclusively by the first metal part 11 and the second metal part 12. The cooling channel 10 is formed by the first metal part 11 and the second metal part 12 as a circumferentially closed cooling channel. Hard soldering can advantageously be used to connect the first metal part 11 to the second metal part 12, such that in the assembled state of the cooler 1, a hard soldering layer is located between the two metal parts 11, 12. Both the first metal part 11 and the second metal part 12 are preferably aluminum parts. Other materials are conceivable for the first metal part 11 and/or the second metal part 12.

In particular, both metal parts 11, 12 are configured as metal sheets. In terms of the shape of the metal parts 11, 12, the first metal part 11 is plate-shaped, in particular an oval-shaped plate, and the second metal part 12 comprises a plate-shaped area and a trapezoidal area in (FIGS. 2 and 3) in cross section. The second metal part 12 may advantageously be produced by means of a deep-drawing process. However, it is also possible for the first metal part 11 and the second metal part 12 to comprise other shapes.

The metal parts 11, 12 and the reinforcing part 13 advantageously form a housing 15 on which an inlet 151 and an outlet 152 for the fluid used as the coolant are located. The inlet 151 and the outlet 152, which are respectively in particular configured as nozzles and thus can also be referred to as coolant nozzles, are located on the second metal part 12 in this exemplary embodiment.

To receive the power electronics 200 to be cooled, the first metal part has a receiving area 110. In this exemplary embodiment, the power electronics 200 include three power electronics units 210, which may also be referred to as power modules and are located in succession in the longitudinal direction 501. Each of the power electronics units 210 may preferably include a carrier plate, conductor paths, and power semiconductors.

The power electronics units 210 are preferably joined to the cooler 100 through which fluid can flow, in particular to the receiving area 110 of the first metal part 11, by means of a layer produced by a soft soldering process or a sintering process, which is thus referred to as a soft soldering layer or sintering layer.

A cooling structure 14 is located in the cooling channel 10, which serves as a surface-enlarging, flow-guiding and heat-transfer-enhancing structure for a fluid used as a coolant, as previously described. In particular, the cooling structure 14 according to FIG. 3 comprises or is a cooling fin structure. To this end, the cooling fin structure may have at least one cooling fin 140 extending in the longitudinal direction of the cooling channel 10 or in a flow direction 504 of the fluid. As can be seen from FIG. 3, the cooling fin 140 is preferably formed from a wave profile that periodically repeats in a direction of repetition. Through-holes 141 are formed through the cooling fin 140, through which the fluid can pass.

The cooling structure 14 is preferably made of a material and/or coated with a material that features a coefficient of thermal conductivity greater than 200 W/(m-K). Advantageously, the cooling fin 10 may be made of aluminum or coated with aluminum. It is also possible that other thermally conductive materials are used for the cooling structure 14 and/or their layer.

The cooling structure 14 is connected to the first metal part 11 and the second metal part 12. Hard soldering may be used to connect the cooling structure 14 to the first metal part 11 and the second metal part 12 as in the connection between the first metal part 11 and the second metal part 12. By connecting the cooling structure 14 to the first metal part 11 and the second metal part 12, the cooler 1 in the area of the cooling channel 10 is supported against internal pressure prevailing therein.

In order to also increase the resistance of the cooler 1 in areas in which the cooling structure 14 cannot serve as a support structure element, and thus to strengthen the construction of the cooler 1 in these areas, the aforementioned reinforcing part 13 is attached to the first metal part 11 and is in particular soldered.

The joining of the first metal part 11 to the second metal part 12 and/or the joining of the cooling structure 14 to the metal parts 11, 12 and/or the joining of the reinforcing part 13 to the first metal part 11 may advantageously occur in the same manufacturing step, in particular by means of a hard solder.

The reinforcing part 13 is located on the first metal part 11 partially outside of an overlap area 16 between the first metal part 11 and the cooling structure 14 and/or the second metal part 12 and the cooling structure 14. In particular, the reinforcing part 13 is located on the first metal part 11, primarily outside the overlap area 16. The arrangement or construction of the reinforcing part 13 will be explained in more detail below.

Looking at FIGS. 1 to 3, it is noted that the reinforcing part 13 in this exemplary embodiment comprises a circumferentially closed recess 130. However, it is also possible that the recess 130 is not closed circumferentially. The recess 130, which can also be considered a recess of the housing 15, is in particular defined by an inner wall 135 of the reinforcing part 13 provided at the location of the receiving area 110. Particularly, the recess 130 circumferentially completely surrounds the receiving area 110. In the finished power electronics arrangement 1000, the power electronics units 210 are located in the recess 130. In particular, the power electronics units 210 may project beyond an outer surface 136 of the reinforcing part 13 in the thickness direction 503. From FIGS. 1 to 3 it is further seen that the power electronics units 210 are positioned on the receiving area 110 at a distance from the inner wall 135. However, contact between the power electronics units 210 and the inner wall 135 is also conceivable.

The reinforcing part 13 comprises a first end area 131, a second end area 132, a first edge area 133 and a second edge area 134. The first edge area 133 is located between and interconnects the first end area 131 and the second end area 133. Accordingly, the second edge area 134 is located between and interconnects the first end area 131 and the second end area 133. Thus, in this exemplary embodiment, the first edge area 133 may also be referred to as the first middle area and the second edge area 134 may also be referred to as the second middle area.

As can be seen in FIG. 2, and in particular in the enlarged part of the cooler 1 shown therein, the first end area 131 advantageously extends in the longitudinal direction 501 from a first end 17 of the cooler 1 (only) to the receiving area 110 of the first metal part 11 and overlaps with the cooling structure 14. That is, the first end area 131 is partially located outside of the overlap area 16. In particular, the first end area 131 is located primarily outside the overlap area 16. The second end area 132 advantageously extends in the longitudinal direction 501 from a second end 18 of the cooler 1 (only) to the receiving area 110 of the first metal part 11 and overlaps with the cooling structure 14. That is, the second end area 132 is partially located outside of the overlap area 16. Particularly, the second end area 132 is located predominantly outside the overlap area 16.

In this configuration of the cooler 1, the reinforcing part 13, the first metal part 11 and the cooling structure 14 overlap. In particular, the first end area 131, the first metal part 11 and the cooling structure 14 as well as the second end area 132, the first metal part 11 and the cooling structure 14 overlap each other. As can be seen from FIG. 2, the extent 604 of the overlap between the first end area 131 of the reinforcing part 13 and the cooling structure 14 in the longitudinal direction 501 is at most ten times, more preferably at most five times, a thickness 601 of the first metal part 11. The same preferably applies to the extent of overlap between the second end area 132 and the cooling structure 14 in the longitudinal direction 501.

FIG. 3 further shows that the first edge area 133 extends in the width direction 502 from a first edge 19 of the cooler 1 (only) to the receiving area 110 and is located exclusively outside the overlap area 16. That is, the first edge area 133 does not overlap with the cooling structure 14. Accordingly, the second edge area 134 extends in the width direction 502 from a second edge 20 of the cooler 1 (only) to the receiving area 110 and is located exclusively outside the overlap area 16. That is, the second edge area 134 does not overlap with the cooling structure 14. However, it is also possible for the first edge area 133 and/or the second edge area 134 to overlap with the cooling structure 14.

A first part of the first end area 131, the first edge area 133 and a first part of the second end area 132 form a first area of the reinforcing part 13 that is formed continuously in the longitudinal direction 501. In other words, a first part of the first end area 131, the first edge area 133 and a first part of the second end area 132 form a first area of the reinforcing part 13 extending from the first end 17 to the second end 18 of the cooler 1. Accordingly, a second part of the first end area 131, the second edge area 134, and a second part of the second end area 132 form a second area of the reinforcing part 13 that is formed continuously in the longitudinal direction 501. In other words, a second part of the first end area 131, the second edge area 134 and a second part of the second end area 132 form a second area of the reinforcing part 13 extending from the first end 17 to the second end 18 of the cooler 1. Overall, the reinforcing part 13 may be referred to as continuous.

As further shown in particular in FIG. 3, the thickness 603 of the reinforcing part 13 is greater than the thickness 601 of the first metal part 11. Furthermore, the thickness 602 of the second metal part 12 is also greater than the thickness 601 of the first metal part 11. In addition, the sum of the thickness 603 of the reinforcing part 13 and the thickness 601 of the first metal part 11 is preferably equal to the thickness 602 of the second metal part 12. However, it is also possible that the sum of the thickness 603 of the reinforcing part 13 and the thickness 601 of the first metal part 11 is greater than the thickness 602 of the second metal part 12. Advantageously, the first metal part 11 has the same thickness 601 throughout. That is to say, the receiving area 110 also has the thickness 601. Accordingly, the thickness 602 of the second metal part 12 and the thickness 603 of the reinforcing part 13 are respectively constant. The fact that the thickness 601 of the first metal part 11, in particular its receiving area 110, is selected relative to the thickness 602 of the second metal part 12 and the thickness 603 of the reinforcing part 13, allows for a minimum heat transfer resistance between the power electronics 200 and the fluid used as the coolant, without affecting the resistance of the cooler 1 to an internal pressure in the cooling channel 10.

By locating the power electronics 200 at the cooler 1 through which fluid can flow and the cooling structure 14 in the cooling channel 111, the heat created during operation of the power electronics 200 may be efficiently transferred from the power electronics 200 first to the first metal part 11 and from there to a fluid flowing through the cooling structure 14 and dissipated. In particular, the cooling structure 14 creates a turbulent flow of the fluid, which further increases the cooling efficiency of the cooler 1.

The cooler structure according to the present invention is reinforced by the reinforcing part 13 against the internal pressure in the cooling channel 10. In particular, the reinforcing part 13 is located on the first metal part 11 at junctions between the first metal part 11 and the second metal part 12. Such connecting points 21 can be seen in FIGS. 2 and 3. Despite the reinforcement of the cooler 1, the reinforcing part 13 does not increase the pressure drop already caused by the cooling structure 14, and therefore the cooling capacity of the cooler 1 is not affected.

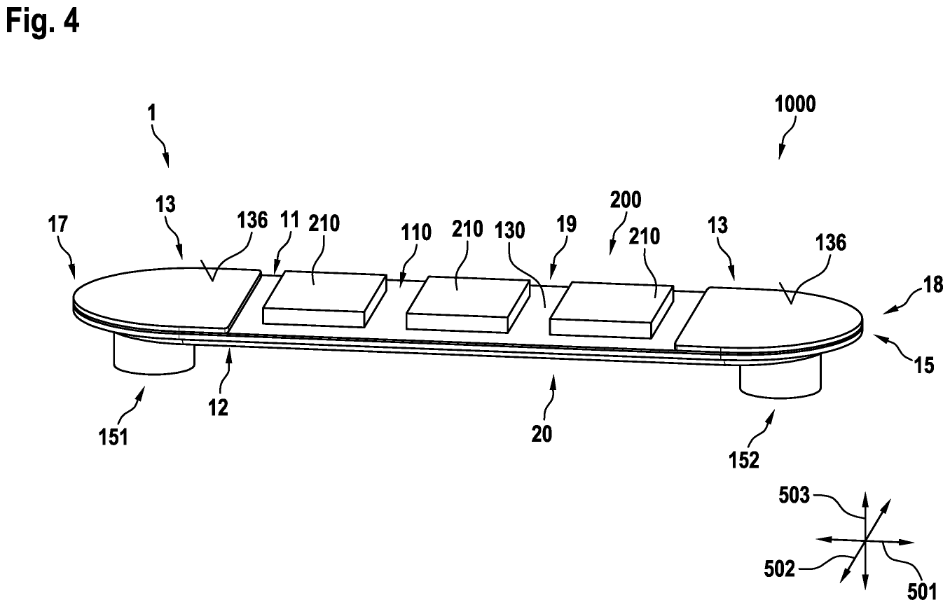

FIG. 4 shows a perspective view of a power electronics arrangement 1000 having power electronics 200 and a cooler 1 through which fluid can flow for cooling the power electronics 200 according to a second exemplary embodiment of the invention.

The power electronics arrangement 1000 according to the second exemplary embodiment differs from that of the first exemplary embodiment in the design of the cooler 1 through which fluid can flow.

As can be seen from FIG. 4, the cooler 1 through which fluid can flow according to the second exemplary embodiment comprises two reinforcing parts 13, wherein the one reinforcing part 13 is preferably provided at the inlet 151 and the other reinforcing part 13 is preferably provided at the outlet 152. In particular, the one reinforcing part 13, in this case the reinforcing part 13 located at the inlet 151, extends in the longitudinal direction 501 from the first end 17 of the cooler 1 (only) to the receiving area 110, wherein the other reinforcing part 13, in this case the reinforcing part 13 located at the outlet 152, extends in the longitudinal direction 101 from the second end 18 of the cooler 1 (only) to the receiving area 110. The two reinforcing parts 13 are preferably identical. The recess 130 of the housing 15 is located between the two reinforcing parts 13. Accordingly, the receiving area 110 is positioned between the two reinforcing portions 13.

Each of the reinforcing parts 13 overlaps with the cooling structure 14 or the overlap area 16 between the first metal part 11 and the cooling structure 14 and/or between the second metal part 12 and the cooling structure 14. That is to say, similar to the reinforcing part 13 of the cooler 1 according to the first exemplary embodiment, each of the reinforcing parts 13 of the cooler 1 according to the second exemplary embodiment is located partially outside the overlap area 16. In particular, each of the reinforcing parts 13 is located predominantly outside the overlap area 16. The reinforcing part 13 located at the inlet 151 corresponds to the first end area 131 of the reinforcing part 13 of the cooler 1 according to the first exemplary embodiment, and the reinforcing part 13 located at the outlet 152 corresponds to the second end area 132 of the reinforcing part 13 of the cooler 1 according to the first exemplary embodiment.

However, it is also possible for at least one of the reinforcing parts 13, in particular both reinforcing parts 13, to be located exclusively outside the overlap area 16. In other words, it is possible for at least one of the reinforcing parts 13, in particular both reinforcing parts 13, to extend from the corresponding end 17, 18 of the cooler 1 (only) to the overlap area 16.

1. A cooler (1) through which fluid can flow for cooling power electronics (200), comprising:
a first metal part (11) and a second metal part (12) connected to each other and defining a cooling channel (10) between them, through which a fluid can flow, wherein the first metal part (11) has a receiving area (110) for receiving the power electronics (200) to be cooled,
a cooling structure (14) located in the cooling channel (10) and connected to the first metal part (11) and the second metal part (12), and
a reinforcing part (13) secured to the first metal part (11).

2. The cooler (1) through which fluid can flow according to claim 1, wherein the cooling channel (10) is circumferentially enclosed exclusively by the first metal part (11) and the second metal part (12).

3. The cooler (1) through which fluid can flow according to claim 1, wherein the first metal part (11) is located between the reinforcing part (13) and the second metal part (12).

4. The cooler (1) through which fluid can flow according to claim 1, wherein the reinforcing part (13) is located on the first metal part (11) at least partially outside an overlap area (16) between the first metal part (11) and the cooling structure (14) and/or between the second metal part (12) and the cooling structure (14).

5. The cooler (1) through which fluid can flow according to claim 4, wherein the reinforcing part (13) is located on the first metal part (11) exclusively outside the overlap area (16), or
wherein the reinforcing part (13) is located partially outside the overlap area (16) and overlaps with the cooling structure (14).

6. The cooler (1) through which fluid can flow according to claim 1, wherein the reinforcing part (13) comprises a recess (130),
wherein the receiving area of the first metal part (11) is located at a location of the recess (130) and/or wherein the recess (130) at least partially surrounds the receiving area (110) in a circumferential direction.

7. The cooler (1) through which fluid can flow according to claim 1, wherein a thickness (603) of the reinforcing part (13) is greater than or equal to a thickness (601) of the first metal part (11).
wherein a sum of the thickness (603) of the reinforcing part (13) and the thickness (601) of the first metal part (11), is greater than or equal to a thickness (602) of the second metal part (12).

8. The cooler (1) through which fluid can flow according to claim 1, wherein the reinforcing part (13) extends in a longitudinal direction (501) from one end (17, 18) of the cooler (1) only to the receiving area (110), or wherein the reinforcing part (13) is continuously formed in the longitudinal direction (501).

9. The cooler (1) through which fluid can flow according to claim 1, wherein the reinforcing part (13) is located on the first metal part (11) at at least one junction between the first metal part (11) and the second metal part (12).

10. The cooler (1) through which fluid can flow according to claim 1, wherein the reinforcing part (13) is plate shaped.

11. A power electronics arrangement (1000) comprising power electronics (200) and a cooler (1) through which fluid can flow according to claim 1, wherein the power electronics (200) are located on the receiving area (110) of the first metal part (11).

12. The power electronics arrangement (1000) according to claim 11, wherein the power electronics (200) are located only on the receiving area (110) of the first metal part (11).

13. The cooler (1) through which fluid can flow according to claim 6, wherein the recess (130) completely surrounds the receiving area (110) in the circumferential direction.

14. The cooler (1) through which fluid can flow according to claim 7, wherein the thickness (603) of the reinforcing part (13) is greater than or equal to the thickness (601) of the first metal part (11) at the receiving area (110),
and/or
wherein a sum of the thickness (603) of the reinforcing part (13) and the thickness (601) of the first metal part (11) at the receiving area (110) is greater than or equal to the thickness (602) of the second metal part (12).
